(19) United States
(12) Patent Application Publication
(10) Pub. No.: US 2022/0380157 A1
(43) Pub. Date: Dec. 1, 2022

(54) SHEET AFFIXING APPARATUS

(71) Applicant: DISCO CORPORATION, Tokyo (JP)

(72) Inventor: Yoshinori KAKINUMA, Tokyo (JP)

(21) Appl. No.: 17/664,730

(22) Filed: May 24, 2022

(30) Foreign Application Priority Data
May 31, 2021 (JP) 2021-091778

(51) Int. Cl. B65H 16/02; B26D 1/42; B65H 20/12

(52) U.S. Cl. CPC B65H 16/02; B26D 1/425; B65H 20/12; B65H 2301/44336

(57) ABSTRACT

A sheet affixing apparatus includes a drawing unit for drawing a sheet from a sheet roll and a sheet cutter for cutting the sheet drawn from the sheet roll by the drawing unit. The sheet cutter includes a sheet support for supporting from below the sheet drawn from the sheet roll by the drawing unit, a cutting knife for cutting the sheet supported by the sheet support, along the sheet support, and a sheet presser for pressing the sheet against the sheet support forwardly of the cutting knife in a direction along which the cutting knife moves in cutting the sheet, when the sheet is cut.

### BACKGROUND OF THE INVENTION

### Field of the Invention

The present invention relates to a sheet affixing apparatus for affixing a sheet to a workpiece.

### Description of the Related Art

In has been known to use a sheet affixing apparatus in a process of grinding and dividing a plate-shaped workpiece such as a wafer with semiconductor devices formed thereon, any of various packaged substrates, ceramic substrates, and glass substrates. The sheet affixing apparatus affixes an adhesive tape of resin or a sheet of thermoplastic resin to a face side of the workpiece for protecting the face side of the workpiece or making it easy to deliver the workpiece to a desired position.

Specifically, the sheet affixing apparatus operates by drawing a sheet from a sheet roll where the sheet has been wound on a core, affixing the sheet to a workpiece, and cutting extra sheet edge portions protruding from and extending along the outer peripheral edge of the workpiece with a cutting knife. In some applications, a rectangular sheet is drawn from a sheet roll and secured to a workpiece. When a predetermined length of the rectangular sheet has been drawn from the sheet, it is cut by a cutting knife (see, for example, JP 2012-143724A).

### SUMMARY OF THE INVENTION

The cutting knife often becomes dull due to repeated use. When the dull cutting knife is used to cut into an end of the sheet, the cutting knife is unable to bring its cutting edge into the sheet, tending to twist the sheet and further reduce its cutting capability. This tendency of the cutting knife is higher if the sheet is made of a pliable material such as polyolefin (PO), instead of a stiffer material such as a polyethylene terephthalate (PET) film.

It is therefore an object of the present invention to provide a sheet affixing apparatus that is capable of reliably cutting a sheet.

In accordance with an aspect of the present invention, there is provided a sheet affixing apparatus for drawing a sheet from a sheet roll where the sheet has been wound on a core and affixing the sheet to a workpiece, including a drawing unit for drawing the sheet from the sheet roll and a sheet cutter for cutting the sheet drawn from the sheet roll by the drawing unit. The sheet cutter includes a sheet support for supporting from below the sheet drawn from the sheet roll by the drawing unit, a cutting knife for cutting the sheet supported by the sheet support, along the sheet support, and a sheet presser for pressing the sheet against the sheet support forwardly of the cutting knife in a direction along which the cutting knife moves in cutting the sheet, when the sheet is cut.

Preferably, the sheet support includes a suction groove for holding the sheet under suction on the sheet support, the suction groove extending in a direction across the direction along which the cutting knife moves in cutting the sheet.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a schematic perspective view illustrating a structural example of a sheet affixing apparatus according to an embodiment of the present invention;

FIG. 2 is a perspective view illustrating by way of example a workpiece to which a sheet is to be affixed by the sheet affixing apparatus illustrated in FIG. 1;

FIG. 3 is an enlarged fragmentary cross-sectional view of the workpiece illustrated in FIG. 2 with the sheet affixed thereto;

FIG. 4 is a plan view of a sheet cutter of the sheet affixing apparatus illustrated in FIG. 1;

FIG. 5 is a front elevational view of the sheet cutter illustrated in FIG. 4;

FIG. 6 is a fragmentary plan view of the sheet cutter illustrated in FIG. 4;

FIG. 7 is a fragmentary side elevational view of the sheet cutter illustrated in FIG. 4;

FIG. 8 is a plan view of a suction groove of the sheet cutter illustrated in FIG. 4;

FIG. 9 is a plan view of a suction groove of a sheet cutter of a sheet affixing apparatus according to a first modification of the embodiment; and

FIG. 10 is a plan view of a suction groove of a sheet cutter of a sheet affixing apparatus according to a second modification of the embodiment.

### DETAILED DESCRIPTION OF THE PREFERRED EMBODIMENTS

Preferred embodiments of the present invention will be described in detail hereinbelow with reference to the accompanying drawings. The present invention is not limited to the details of the embodiments described below. The components described below cover those which could easily be anticipated by those skilled in the art and those which are essentially identical to those described above. Further, the arrangements described below can be combined in appropriate manners. Various omissions, replacements, or changes of the arrangements can be made without departing from the scope of the present invention. In the description to be described below, those components that are identical to each other are denoted by identical reference characters, and will be omitted from description.

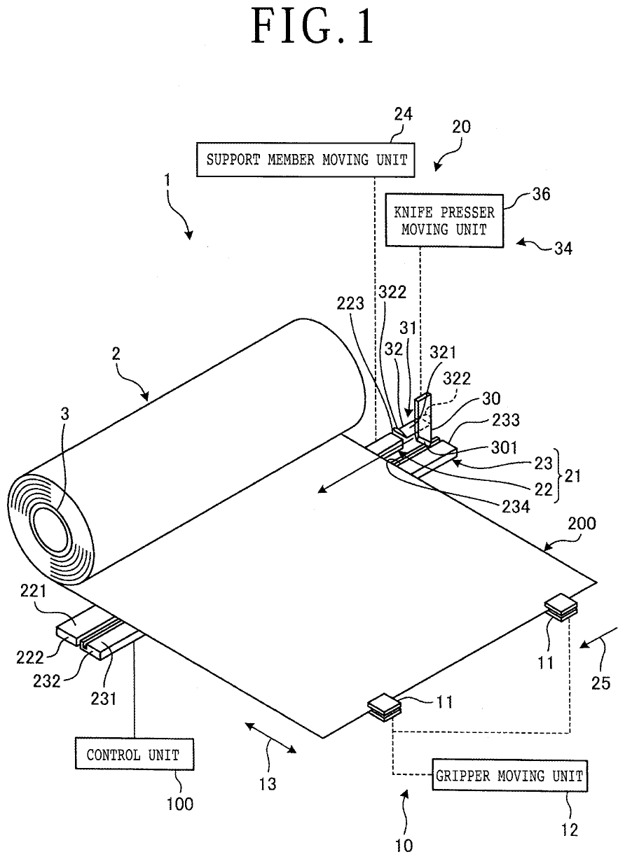

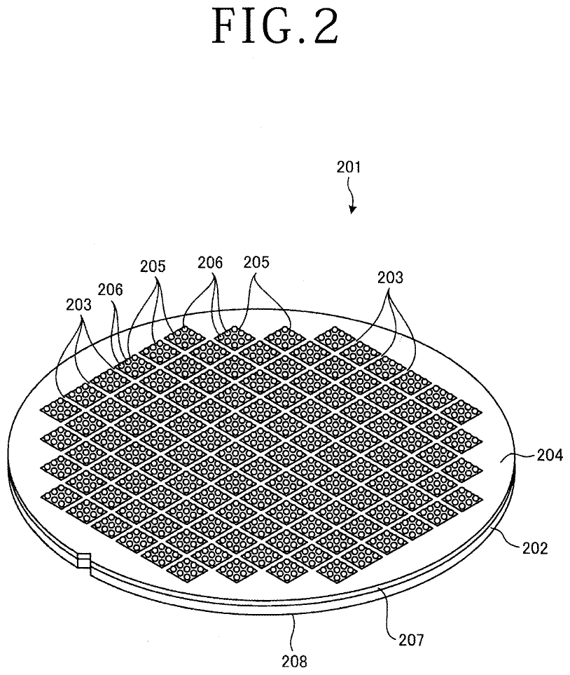

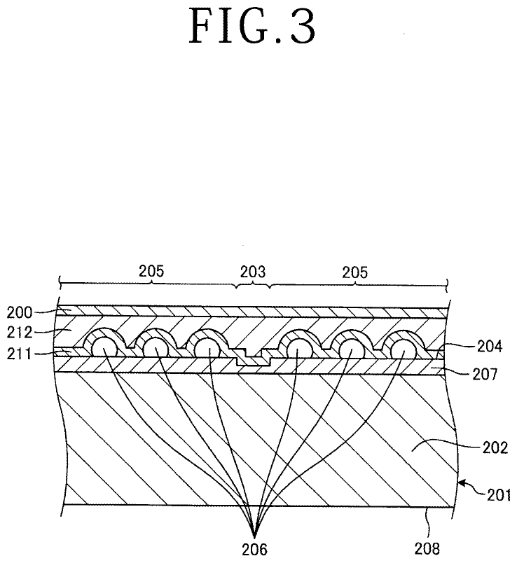

A sheet affixing apparatus according to a preferred embodiment of the present invention will be described below. FIG. 1 schematically illustrates in perspective a structural example of the sheet affixing apparatus according to the embodiment. FIG. 2 illustrates by way of example in perspective view a workpiece to which a sheet is to be affixed by the sheet affixing apparatus illustrated in FIG. 1. FIG. 3 illustrates in enlarged fragmentary cross section the workpiece illustrated in FIG. 2 with the sheet affixed thereto.

The sheet affixing apparatus, generally denoted by 1 in FIG. 1, is an apparatus for affixing a sheet 200 to the workpiece, denoted by 201 in FIG. 2. The workpiece 201 to which the sheet 200 is to be affixed by the sheet affixing apparatus 1 includes a wafer such as a semiconductor wafer or an optical wafer in the shape of a circular plate including a substrate 202 (see FIG. 2) made of silicon (Si), sapphire (Al₂O₃), gallium arsenide (GaAs), silicon carbide (SiC), or the like.

The workpiece 201 includes a plurality of devices 205 formed in respective areas demarcated on a face side 204 thereof by a grid of intersecting projected dicing lines 203. Each of the devices 205 has a plurality of bumps 206 that are electrically connected to electrodes of the device 205 and that protrude from the face side 204, as illustrated in FIG. 2. The devices 205 are, for example, circuits such as integrated circuits (ICs) or large-scale-integration (LSI) circuits, image sensors such as charge-coupled devices (CCDs) or complementary metal-oxide-semiconductor (CMOS) sensors, or microelectromechanical systems (MEMS) or the like.

The bumps 206 are made of electrically conductive metal. According to the present embodiment, the bumps 206 are of a spherical shape. The bumps 206 are used to electrically connect the devices 205 to electrodes on boards or the like, not illustrated, on which the devices 205 will be mounted. According to the present embodiment, the bumps 206 of the devices 205 provide surface irregularities on the face side 204 of the workpiece 201. According to the present invention, however, the devices 205 may be free of the bumps 206. According to the present invention, further, the workpiece 201 is not limited to a wafer and may be a rectangular resin-packaged substrate, a ceramic substrate, a glass substrate, or the like each having a plurality of resin-encapsulated devices.

According to the present embodiment, the workpiece 201 includes a functional layer 207 layered on a face side of the substrate 202. The functional layer 207 includes an insulative film having a low dielectric constant, hereinafter referred to as a “low-k film,” in the form of an inorganic film made of fluorinated silicon oxide (SiOF), borosilicate glass (BSG) (silicon optical bench (SiOB)), or the like or an organic film such as a polymer film made of polyimide or parylene, and an electrically conductive film made of electrically conductive metal. The low-k film and the electrically conductive film are layered together, making up the devices 205. The electrically conductive film provides the circuits of the devices 205. Specifically, the devices 205 are made up of a plurality of layered low-k films and a plurality of electrically conductive films layered between the low-k films. The functional layer 207 includes portions extending respectively along the projected dicing lines 203. These portions of the functional layer 207 are made of a low-k film and free of an electrically conductive film except for test element groups (TEGs). The TEGs are assessment elements for finding design and fabrication problems that may occur on the devices 205.

According to the present embodiment, the workpiece 201 is processed as follows. A resin sheet 211, a resin layer 212, and a sheet 200 illustrated in FIG. 3 are successively layered on the face side 204 of the workpiece 201. While the face side 204 is being held on a chuck table of a grinding apparatus with the sheet 200 interposed therebetween, a reverse side 208 of the workpiece 201 is ground by the grinding apparatus to thin down the workpiece 201 to a predetermined finished thickness. Thereafter, the workpiece 201 is divided into the individual devices 205 along the projected dicing lines 203.

According to the present embodiment, the resin sheet 211 includes a thin flexible sheet made of a synthetic resin, i.e., PO, in the present embodiment. The resin sheet 211 is affixed to the face side 204 and the bumps 206 in intimate contact therewith.

According to the present embodiment, the resin layer 212 is made of an ultraviolet-curable liquid resin that is cured upon exposure to ultraviolet radiation. The resin layer 212 is layered on the resin sheet 211. The sheet 200 includes a thin flexible film made of a synthetic resin, i.e., PO, in the present embodiment. The sheet 200 is layered on the resin layer 212.

After the resin sheet 211 has been affixed to the face side 204 and the bumps 206 in intimate contact therewith, the resin sheet 211 is coated with the liquid resin to be processed into the resin layer 212. Then, the applied liquid resin has its surface flattened along the face side of the substrate 202. The liquid resin is then cured into the resin layer 212 by being irradiated with the ultraviolet radiation, after which the sheet 200 is affixed to the resin layer 212.

According to the present embodiment, the sheet affixing apparatus 1 illustrated in FIG. 1 draws the sheet 200 from a sheet roll 2 where the sheet 200 has been wound on a core 3 and affixes the sheet 200 to the face side 204 of the workpiece 201, or more specifically, the resin layer 212 layered on the resin sheet 211 on the face side 204 of the workpiece 201. As illustrated in FIG. 1, the sheet affixing apparatus 1 includes the sheet roll 2, a drawing unit 10, a sheet cutter 20, a sheet affixing unit, not illustrated, and a control unit 100.

The sheet roll 2 includes the core 3 that is rotatably supported in a casing or the like, not illustrated, of the sheet affixing apparatus 1, the core 3 being rotatable about its own central axis. The sheet 200 in an elongate web form is wound around the core 3, making up the sheet roll 2.

The drawing unit 10 pulls the sheet 200 from the sheet roll 2 as the core 3 of the sheet roll 2 rotates about the central axis thereof. The drawing unit 10 includes a pair of grippers 11 for gripping the leading end of the sheet 200 and a gripper moving unit 12 for moving the grippers 11. The grippers 11 are spaced apart from each other transversely across the sheet 200, i.e., axially along the central axis of the core 3.

The gripper moving unit 12 moves the grippers 11 toward and away from the sheet roll 2 along directions perpendicular to the longitudinal directions of the sheet roll 2, i.e., the axial directions of the core 3. The directions along which the gripper moving unit 12 moves the grippers 11 toward and away from the sheet roll 2 will be referred to as “drawing directions 13” indicated by an arrow in FIG. 1, etc.

The drawing unit 10 operates as follows. The gripper moving unit 12 moves the grippers 11 toward the sheet roll 2, and the grippers 11 grip the leading end of the sheet 200 from the sheet roll 2. After the grippers 11 have gripped the leading end of the sheet 200, the gripper moving unit 12 moves the grippers 11 away from the sheet roll 2, pulling the sheet 200 from the sheet roll 2.

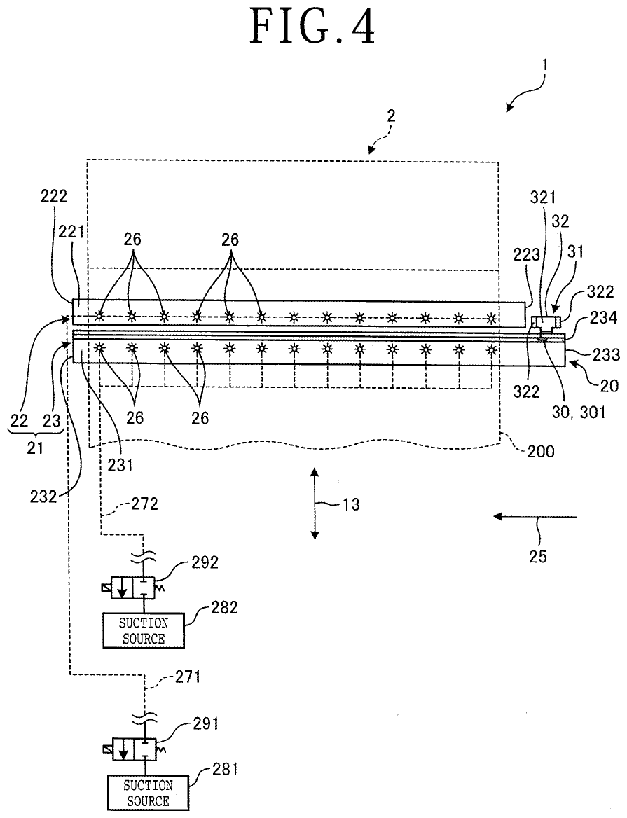

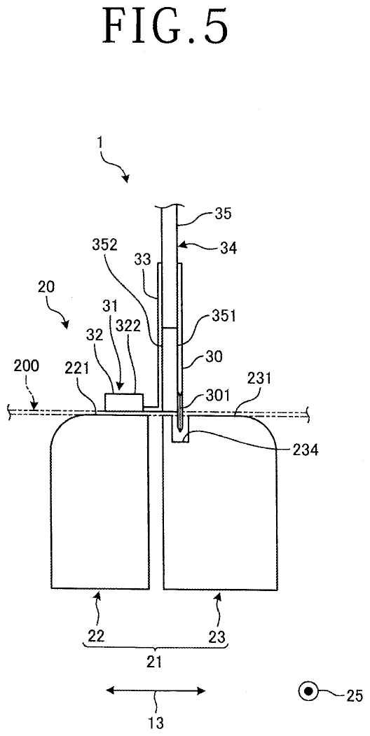

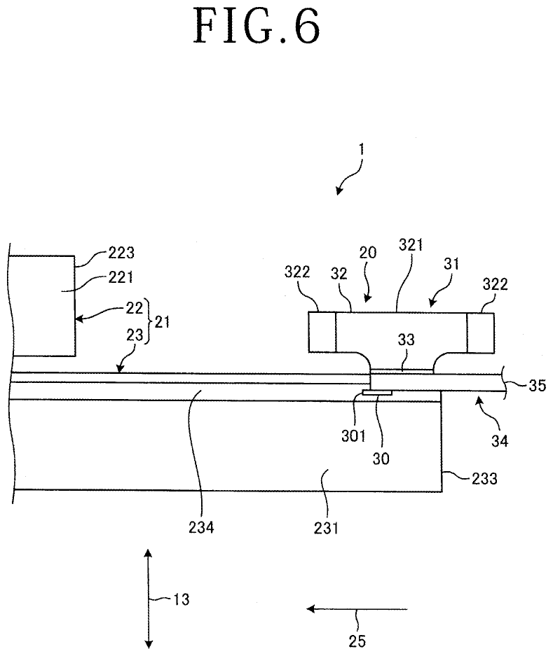

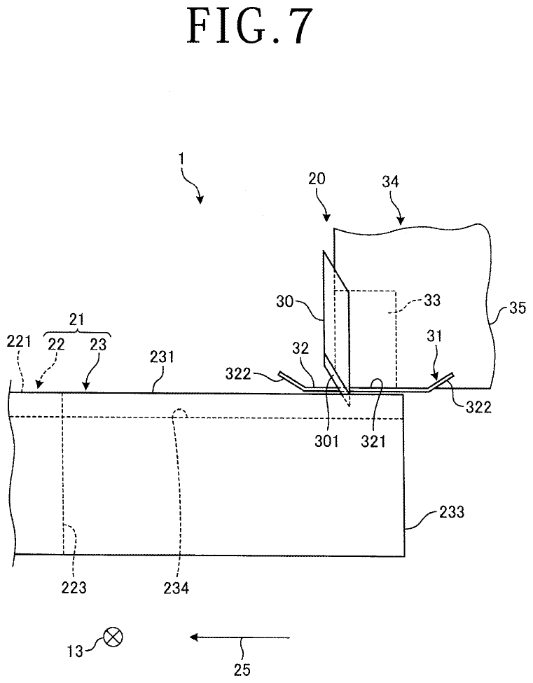

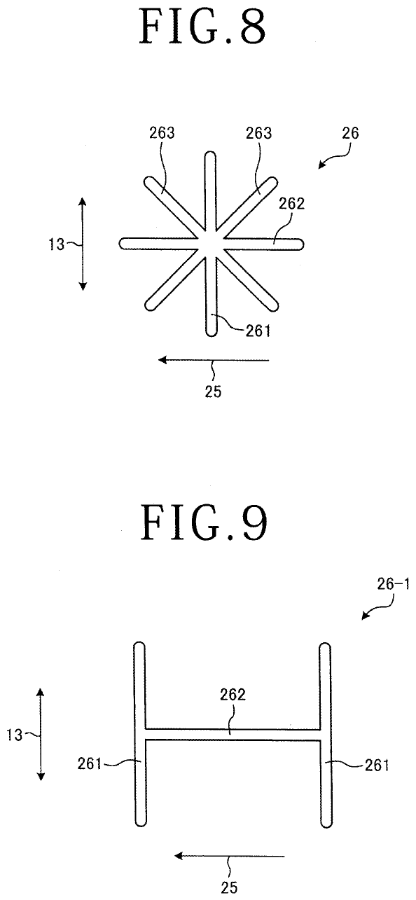

The sheet cutter 20 serves to cut the sheet 200 drawn from the sheet roll 2 by the drawing unit 10. FIG. 4 illustrates in plan the sheet cutter 20 of the sheet affixing apparatus 1 illustrated in FIG. 1. FIG. 5 illustrates in front elevation the sheet cutter 20 illustrated in FIG. 4. FIG. 6 illustrates in fragmentary plan the sheet cutter 20 illustrated in FIG. 4. FIG. 7 illustrates in fragmentary side elevation the sheet cutter 20 illustrated in FIG. 4. FIG. 8 illustrates in plan a suction groove of the sheet cutter 20 illustrated in FIG. 4.

As illustrated in FIGS. 4, 5, 6, and 7, the sheet cutter 20 includes a sheet support 21, a cutting knife 30, a sheet presser 31, and a knife presser moving mechanism 34.

The sheet support 21 supports from below the sheet 200 drawn from the sheet roll 2 by the drawing unit 10. The sheet support 21 includes a first support member 22, a second support member 23, and a support member moving unit 24 (see FIG. 1).

The first support member 22 and the second support member 23 are disposed beneath the sheet 200 drawn from the sheet roll 2 by the drawing unit 10. The first support member 22 and the second support member 23 are each shaped as a strip having longitudinal directions parallel to the central axis of the core 3 and the transverse directions of the sheet 200. The first support member 22 and the second support member 23 are spaced apart from each other in the longitudinal directions of the sheet 200.

The first support member 22 and the second support member 23 have respective upper surfaces 221 and 231 lying flatwise horizontally. The first support member 22 is disposed closer to the sheet roll 2 than the second support member 23 is. According to the present embodiment, as illustrated in FIG. 4, the first support member 22 is shorter than the second support member 23, and the first support member 22 and the second support member 23 are arrayed along the drawing directions 13. The first support member 22 and the second support member 23 have respective ends 222 and 232 aligned with each other along the drawing directions 13 and respective other ends 223 and 233 staggered such that the other end 223 of the first support member 22 is closer to the end 222 thereof than the other end 233 of the second support member 23 is to the end 232 thereof.

The first support member 22 is vertically movable by the support member moving unit 24 between a position where the upper surface 221 thereof lies flush with the upper surface 231 of the second support member 23 and a position where the upper surface 221 thereof is higher than the upper surface 231 of the second support member 23. The second support member 23 has an elongate slot 234 defined therein that is open at and recessed from the upper surface 231 and that extends straight in the longitudinal directions of the second support member 23, i.e., transversely across the sheet 200. The elongate slot 234 has a longitudinal direction referred to as a “moving direction 25 of the cutting knife 30” indicated by an arrow in FIG. 1, etc. The moving direction 25 of the cutting knife 30 is perpendicular to the drawing directions 13.

The sheet support 21 supports from below the sheet 200 that has been drawn from the sheet roll 2 by the drawing unit 10, onto the upper surfaces 221 and 231 of the respective first and second support members 22 and 23, when the upper surfaces 221 and 231 lie flush with each other. The sheet support 21 has a plurality of suction grooves 26 defined therein for holding under suction the sheet 200 placed on the upper surfaces 221 and 231 of the respective first and second support members 22 and 23.

According to the present embodiment, the suction grooves 26 are defined in both the first support member 22 and the second support member 23 and are open at and recessed from the upper surfaces 221 and 231. The suction grooves 26 defined in the second support member 23 are more spaced from the first support member 22 than the slot 234. According to the present embodiment, the suction grooves 26 are disposed at spaced intervals in the longitudinal directions of the first and second support members 22 and 23.

The suction grooves 26 that are open at the upper surface 221 of the first support member 22 are connected to a first suction source 281 through a first suction channel 271 extending through the first support member 22, etc. The first suction channel 271 includes a first on/off valve 291. Similarly, the suction grooves 26 that are open at the upper surface 231 of the second support member 23 are connected to a second suction source 282 through a second suction channel 272 extending through the second support member 23, etc. The second suction channel 272 includes a second on/off valve 292. When the suction sources 281 and 282 are actuated and the on/off valves 291 and 292 are opened, the suction grooves 26 are evacuated by suction forces from the suction sources 281 and 282, holding the sheet 200 under suction on the upper surfaces 221 and 231 to thereby secure the sheet 200 to the first and second support members 22 and 23.

According to the present embodiment, as illustrated in FIG. 8, each of the suction grooves 26 includes a straight orthogonal portion 261 extending parallel to the drawing directions 13 and perpendicularly to or across the moving direction 25 of the cutting knife 30, a straight parallel portion 262 extending parallel to the moving direction 25 of the cutting knife 30, and a pair of straight crossing portions 263 extending across both the drawing directions 13 and the moving direction 25 of the cutting knife 30. According to the present embodiment, the orthogonal portion 261, the parallel portion 262, and the crossing portions 263 cross each other at the center of the suction groove 26. The crossing portions 263 are inclined to both the drawing directions 13 and the moving direction 25 of the cutting knife 30 at an angle of 45 degrees.

The cutting knife 30 serves to cut the sheet 200 supported on the sheet support 21 along the slot 234 of the sheet support 21. The cutting knife 30 is shaped as a ribbon of plate extending longitudinally parallel to vertical directions and has on a lower end thereof a cutting edge 301 for cutting into the sheet 200 to severe the sheet 200. The cutting edge 301 is inserted in the slot 234.

The sheet presser 31 serves to press the sheet 200 against the sheet support 21 forwardly of the cutting knife 30 with respect to the moving direction 25 of the cutting knife 30 when the cutting knife 30 cuts the sheet 200. The sheet presser 31 includes a pressing foot 32 and an upstanding leg 33 extending upwardly from a transverse end of the pressing foot 32.

The pressing foot 32 is of a rectangular shape, and its longitudinal directions extend parallel to the moving direction 25 of the cutting knife 30. The pressing foot 32 includes a parallel portion 321 extending parallel to the upper surfaces 221 and 231 of the first and second support members 22 and 23, i.e., the horizontal directions, and a pair of upwardly extending portions 322 joined respectively to both ends of the parallel portion 321 along the moving direction 25 of the cutting knife 30 and slanted progressively away from the upper surfaces 221 and 231 in directions away from the parallel portion 321.

The knife presser moving mechanism 34 includes an attachment member 35 illustrated in FIGS. 5, 6, and 7 and a knife presser moving unit 36 illustrated in FIG. 1. According to the present embodiment, the attachment member 35 is shaped as a plate extending in the vertical directions. The cutting knife 30 is attached to a surface 351 of the attachment member 35, the surface 351 extending parallel to the vertical directions and facing in one of the drawing directions 13, and the upstanding leg 33 of the sheet presser 31 is attached to another surface 352 of the attachment member 35, the upstanding leg 33 extending parallel to the vertical directions and facing in the other of the drawing directions 13. The attachment member 35 is disposed above the first and second support members 22 and 23 and inserts the cutting edge 301 of the cutting knife 30 into the slot 234.

The knife presser moving unit 36 serves to move the attachment member 35 and hence the cutting knife 30 and the sheet presser 31 in directions parallel to the central axis of the core 3 of the sheet roll 2, i.e., in horizontal directions, over the entire length of the first and second support members 22 and 23. The cutting knife 30 and the sheet presser 31 are attached to the attachment member 35 at such positions that when the attachment member 35 is positioned above the other end 233 of the second support member 23 by the knife presser moving unit 36, one of the upwardly extending portions 322 of the pressing foot 32 of the sheet presser 31 is closer to the ends 222 and 232 of the first and second support members 22 and 23, i.e., the sheet 200 supported on the sheet support 21, than the cutting edge 301 of the cutting knife 30.

Further, the sheet presser 31 is attached to the attachment member 35 at such a position that when the attachment member 35 is positioned above the other end 233 of the second support member 23 by the knife presser moving unit 36, one of the upwardly extending portions 322 of the pressing foot 32 of the sheet presser 31 is spaced from the first support member 22. In addition, the sheet presser 31 is attached to the attachment member 35 at such a position that when the attachment member 35 is moved in a direction parallel to the central axis of the core 3 of the sheet roll 2, i.e., a horizontal direction, by the knife presser moving unit 36, the pressing foot 32 of the sheet presser 31 moves over and along the upper surface 221 of the first support member 22.

The sheet affixing unit serves to affix the sheet 200 drawn from the sheet roll 2 by the drawing unit 10 and cut into a length, which will also be referred to as the “sheet 200,” by the sheet cutter 20 to the face side 204 of the workpiece 201, or more specifically, the resin layer 212 layered on the resin sheet 211 on the face side 204 of the workpiece 201. Specifically, the sheet affixing unit positions the workpiece 201 where the resin sheet 211 and the resin layer 212 are successively layered on the face side 204 thereof, and affixes the sheet 200 that has been delivered by a delivery unit, not illustrated, to the resin layer 212 on the workpiece 201.

The control unit 100 controls the various components referred to above of the sheet affixing apparatus 1, to enable the sheet affixing apparatus 1 to perform a sheet affixing process for affixing the sheet 200 to the workpiece 201. The control unit 100 is a computer that includes a processing device having a microprocessor such as a central processing unit (CPU), a storage device having a memory such as a read only memory (ROM) or a random access memory (RAM), and an input/output interface and that is capable of executing computer programs.

The processing device of the control unit 100 executes computer programs stored in the ROM on the RAM to generate control signals for controlling the sheet affixing apparatus 1. The processing device then outputs the generated control signals through the input/output interface to the components of the sheet affixing apparatus 1.

To the control unit 100, there are electrically connected a display unit such as a liquid display device for displaying statuses and images of a sheet affixing process and an input unit that is used by an operator to register processing contents information, etc. The input unit includes at least one of a touch panel provided by the input unit, a keyboard, etc.

An example of a sheet affixing process for affixing the sheet 200 that is carried out by the sheet affixing apparatus 1 will be described below. First, the control unit 100 controls the knife presser moving unit 36 to position the attachment member 35, i.e., the cutting knife 30 and the sheet presser 31, above the other end 233 of the second support member 23, and opens the first on/off valve 291 and closes the second on/off valve 292 to hold the sheet 200 from the sheet roll 2 under suction on the upper surface 221 of the first support member 22, securing the sheet 200 in position thereon. Then, the control unit 100 controls the support member moving unit 24 to lift the first support member 22 once and then lower the first support member 22 to a position where the upper surface 221 thereof lies flush with the upper surface 231 of the second support member 23. When the upper surface 221 of the first support member 22 lies flush with the upper surface 231 of the second support member 23, the control unit 100 closes the first on/off valve 291. Since the sheet 200 has been drawn from the sheet roll 2 by the first support member 22 that has once been lifted, the sheet 200 is placed on the upper surfaces 221 and 231 of the first and second support members 22 and 23, covering the suction grooves 26 in the upper surfaces 221 and 231. The control unit 100 then controls the grippers 11 to grip the leading end of the sheet 200.

The control unit 100 opens the on/off valves 291 and 292 to evacuate the suction grooves 26 with the suction forces from the suction sources 281 and 282, holding the sheet 200 under suction on the upper surfaces 221 and 231 to thereby secure the sheet 200 to the first and second support members 22 and 23. The control unit 100 then controls the knife presser moving unit 36 to move the attachment member 35, i.e., the cutting knife 30 and the sheet presser 31, toward the ends 222 and 232 of the first and second support members 22 and 23 along the moving direction 25 of the cutting knife 30.

When the sheet presser 31 reaches the end 222 of the first support member 22, a leading one of the upwardly extending portions 322 of the pressing foot 32 of the sheet presser 31 rides onto a transverse end of the sheet 200 on the upper surface 221 of the first support member 22. As the knife presser moving unit 36 further moves the attachment member 35, the parallel portion 321 of the pressing foot 32 is placed on the sheet 200, pressing the sheet 200 against the upper surface 221 of the first support member 22 and also against the upper surface 231 of the second support member 23. Thereafter, the cutting edge 301 of the cutting knife 30 cuts into the transverse end of the sheet 200. As the attachment member 35, i.e., the cutting knife 30 and the sheet presser 31, moves further toward the ends 222 and 232 of the first and second support members 22 and 23, the cutting knife 30 cuts the sheet 200 transversely thereacross while the sheet presser 31 is pressing the sheet 200 against the upper surfaces 221 and 231 of the first and second support members 22 and 23.

When the cutting knife 30 has cut the sheet 200 transversely across its entire width, the control unit 100 controls the knife presser moving unit 36 to move the attachment member 35, i.e., the cutting knife 30 and the sheet presser 31, toward the other ends 223 and 233 of the first and second support members 22 and 23 and to position the attachment member 35, i.e., the cutting knife 30 and the sheet presser 31, above the other end 233 of the second support member 23. The control unit 100 closes the second on/off valve 292 and controls the delivery unit, not illustrated, to deliver the cut length of the sheet 200 from the sheet roll 2 toward the sheet affixing unit, not illustrated. The control unit 100 controls the sheet affixing unit to affix the cut sheet 200 to the resin layer 212 on the face side 204 of the workpiece 201.

After the cut sheet 200 has been delivered to the sheet affixing unit, the control unit 100 opens the first on/off valve 291 to hold the sheet 200 from the sheet roll 2 under suction on the upper surface 221 of the first support member 22, securing the sheet 200 in position thereon. Then, the control unit 100 controls the support member moving unit 24 to lift the first support member 22 once and then lower the first support member 22 to the position where the upper surface 221 thereof lies flush with the upper surface 231 of the second support member 23. The sheet 200 is drawn from the sheet roll 2 by the first support member 22 that is lifted. When the upper surface 221 of the first support member 22 lies flush with the upper surface 231 of the second support member 23, the control unit 100 closes the first on/off valve 291. One cycle of the sheet affixing process for affixing the sheet 200 to the workpiece 201 is now ended.

The sheet affixing apparatus 1 according to the embodiment described above offers the following advantages. The cutting edge 301 of the cutting knife 30 cuts into the sheet 200 after the sheet presser 31 has pressed the sheet 200 against the upper surface 231 of the second support member 23 of the sheet support 21. Therefore, the sheet 200 is reliably prevented from being twisted when the cutting edge 301 cuts into the sheet 200. Even if the cutting knife 30 has become dull due to repeated use, it can cut the sheet 200 relatively easily without twisting the sheet 200. As a result, the sheet affixing apparatus 1 is capable of reliably cutting the sheet 200.

Further, as the sheet affixing apparatus 1 holds the sheet 200 under suction on the upper surfaces 221 and 231 of the first and second support members 22 and 23 of the sheet support 21, securing the sheet 200 in position thereon, the sheet affixing apparatus 1 can reliably secure the sheet 200 in position by sandwiching the sheet 200 between the sheet presser 31 and the sheet support 21.

Moreover, each of the suction grooves 26 defined in the upper surfaces 221 and 231 of the first and second support members 22 and 23 includes the orthogonal portion 261 and the crossing portions 263 that extend across the moving direction 25 of the cutting knife 30. The orthogonal portion 261 and the crossing portions 263 thus oriented make the sheet 200 further less likely to be twisted when the cutting edge 301 of the cutting knife 30 cuts into the sheet 200.

### [Modifications]

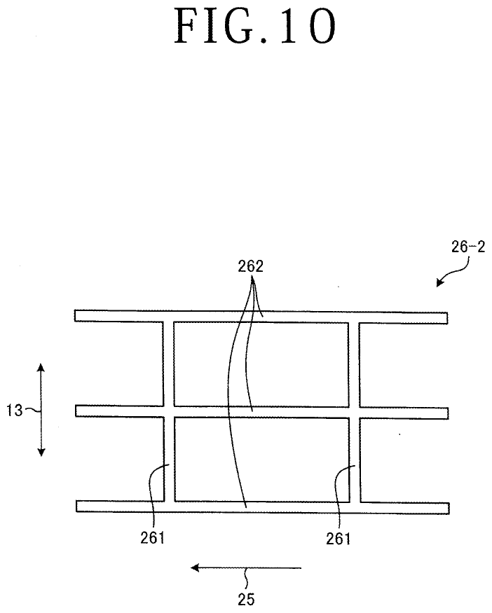

Sheet affixing apparatuses according to modifications of the above embodiment will be described below with reference to FIGS. 9 and 10. FIG. 9 illustrates in plan a suction groove of a sheet cutter of a sheet affixing apparatus according to a first modification of the embodiment. FIG. 10 illustrates in plan a suction groove of a sheet cutter of a sheet affixing apparatus according to a second modification of the embodiment. Those parts illustrated in FIGS. 9 and 10 that are identical to those according to the embodiment described above are denoted by identical reference characters and will be omitted from description below.

The sheet affixing apparatuses according to the first and second modifications of the embodiment are similar to the sheet affixing apparatus 1 according to the embodiment except that suction grooves 26-1 and 26-2 according to the first and second modifications are different in planar shape from the suction groove 26 according to the embodiment.

Specifically, as illustrated in FIG. 9, the suction groove 26-1 of the sheet affixing apparatus according to the first modification has a single straight parallel portion 262 extending parallel to the moving direction 25 of the cutting knife 30 and having opposite ends joined centrally to two respective straight orthogonal portions 261 extending across the moving direction 25 of the cutting knife 30.

As illustrated in FIG. 10, the suction groove 26-2 of the sheet affixing apparatus according to the second modification has three straight parallel portions 262 that extend parallel to the moving direction 25 of the cutting knife 30 and that are spaced at intervals along the drawing directions 13 and two straight orthogonal portions 261 that extend across the moving direction 25 of the cutting knife 30 and that are spaced at an interval along the moving direction 25. The orthogonal portions 261 extend across and joined to the parallel portions 262.

The sheet affixing apparatus according to the first and second modifications are advantageous in that, since the cutting edge 301 of the cutting knife 30 cuts into the sheet 200 after the sheet presser 31 has pressed the sheet 200 against the upper surface 231 of the second support member 23 of the sheet support 21, the sheet 200 is reliably prevented from being twisted when the cutting edge 301 cuts into the sheet 200, and the sheet affixing apparatus can reliably cut the sheet 200.

Further, inasmuch as each of the suction grooves 26-1 and 26-2 includes the orthogonal portions 261 extending across the moving direction 25 of the cutting knife 30, the sheet 200 is further less likely to be twisted when the cutting edge 301 of the cutting knife 30 cuts into the sheet 200.

The present invention should not be construed as being limited to the embodiment and modifications described above. Various changes and modifications can be made therein without departing from the scope of the prevent invention. According to the present invention, for example, the sheet 200 to be affixed by the sheet affixing apparatus 1 may further include an adhesive layer having adhesive power. According to the present invention, further, the workpiece 201 to which the sheet 200 is to be affixed is not limited to the structure where the resin sheet 211 and the resin layer 212 are successively layered on the face side 204.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A sheet affixing apparatus for drawing a sheet from a sheet roll where the sheet has been wound on a core and affixing the sheet to a workpiece, comprising:
a drawing unit for drawing the sheet from the sheet roll; and
a sheet cutter for cutting the sheet drawn from the sheet roll by the drawing unit,
wherein the sheet cutter includes
a sheet support for supporting from below the sheet drawn from the sheet roll by the drawing unit,
a cutting knife for cutting the sheet supported by the sheet support, along the sheet support, and
a sheet presser for pressing the sheet against the sheet support forwardly of the cutting knife in a direction along which the cutting knife moves in cutting the sheet, when the sheet is cut.

2. The sheet affixing apparatus according to claim 1, wherein the sheet support includes a suction groove for holding the sheet under suction on the sheet support, the suction groove extending in a direction across the direction along which the cutting knife moves in cutting the sheet.
